(19) United States
(12) Patent Application Publication
(10) Pub. No.: US 2024/0136388 A1
(43) Pub. Date: Apr. 25, 2024

(54) Method for fabricating radiation-hardened heterojunction photodiodes

(71) Applicants: THALES, MEUDON (FR); COMMISSARIAT A L’ENERGIE ATOMIQUE ET AUX ENERGIES ALTERNATIVES, Paris (FR)

(72) Inventors: Stéphane DEMIGUEL, Cannes la Bocca (FR); Jean-Luc REVERCHON, Palaiseau (FR); Marco BENFANTE, Massy (FR)

(21) Appl. No.: 18/381,038

(22) Filed: Oct. 16, 2023

(30) Foreign Application Priority Data
Oct. 19, 2022 (FR) 2210840

(51) Int. Cl. H01L 27/146

(52) U.S. Cl. CPC H01L 27/14694; H01L 27/14649

(57) ABSTRACT

A method for fabricating an optoelectronic component includes at least one photodiode, the steps of the method making it possible to move the electric carrier collection field to the layer least sensitive to radiation, thus reducing the influence of irradiation on the dark current.

### CROSS-REFERENCE TO RELATED APPLICATION

This application claims priority to foreign French patent application No. FR 2210840, filed on Oct. 20, 2022, the disclosure of which is incorporated by reference in its entirety.

### FIELD OF THE INVENTION

The present invention relates to the field of heterojunction photodiodes, and more specifically to a method for fabricating such photodiodes, of the single-element type or in array form, allowing an improvement in their behaviour in the face of radiation, in particular for space applications.

### BACKGROUND

Free-space optical communications are an alternative to microwave solutions under suitable atmospheric transmission conditions. An essential difficulty is that of the aiming between a source (i.e. a transmitter) and a destination (i.e. a detector). Aiming requires opto-mechanical tracking, which is not trivial.

Tracking solutions between satellites based on opto-mechanical devices allow servo-control between two satellites even in low orbits. The detection chain requires at least a dedicated fast photodiode and a function for locating the source by way of an imager.

An imager composed of a photodiode array has the advantage of working over a wide field without opto-mechanical tracking or positioning elements. However, a conventional imager limits the bandwidth for a pixel to a few tens of Mbps for read noise limitation reasons.

A preferred wavelength range is known to be infrared, which benefits from lower diffusion by aerosols. The near-infrared range makes it possible to benefit from the development of components for fibre optics for telecommunications up to 1.65 μm wavelengths.

InGaAs, i.e. indium gallium arsenide, which is an alloy of indium arsenide and gallium arsenide, materials on an InP substrate are materials of choice for components in free-space optical communications. Gallium arsenide can efficiently convert electricity into coherent light, and the components favour wavelengths beyond 1.3 μm, in particular 1.55 μm, which is a wavelength of many commercially available sources.

These materials can also be used for components in array form in observation instruments aimed at a reduced SWIR (Short-Wave InfraRed) band, cutting at 1.65 μm.

However, it has been found that detectors in a single-element or an array format that are based on InGaAs materials are very fragile in respect of irradiation during space missions. Many studies have shown an increase in the dark current and the presence of telegraphist noise, i.e. an untimely increase in the dark current level.

Indeed, InGaAs technology has a sensitivity to irradiation that is exacerbated by the electric field present in the active region of the structure.

Therefore, existing solutions, which are based on PIN (Positive Intrinsic Negative) photodiode arrays and have an internal electric field in the absorbent InGaAs material, have the major disadvantage of being sensitive to irradiation because the material with the narrowest forbidden band (bandgap) is the most sensitive.

There is, then, a need for single-element or array photodiodes that have reduced sensitivity to irradiation, in order to reduce the dark current.

In particular, there is a need for structures fabricated using type-III-V materials, such as, for example, InGaAs semiconductors on an InP (i.e. indium phosphide, which is a type-III-V binary semiconductor) substrate, also using ternary or quaternary InAlAs/InGaAsP materials, and in which the electric field is outside the InGaAs absorption region.

Such structures must be able to be used for optical communications and for observation in space applications.

The present invention meets these needs.

### SUMMARY OF THE INVENTION

One subject of the present invention is a method for fabricating an optoelectronic component comprising at least one photodiode.

Advantageously, the method of the invention makes it possible to place the electric carrier collection field in the layer least sensitive to radiation, thus reducing the influence of irradiation on the dark current.

The method of the invention can be used to produce photodiode arrays for observation instruments aimed at a reduced SWIR (Short-Wave InfraRed) band, cutting at 1.65 μm instead of cutting conventionally at 2.5 μm.

More generally, the method of the invention can be extended to the entire band without major modifications; only the active region and certain adaptation layers need to be modified in the first order, using an InGaAsSb alloy on a GaSb substrate or a superlattice of the InGaAs/GaAsSb family on an InP substrate.

The method of the invention can be used to fabricate components less sensitive to irradiation in type-III-V semiconductor materials, in particular the InGaAs material, which has the advantage of operating at non-cryogenic temperatures, unlike the HgCdTe material usually used for space applications.

In order to obtain the desired results, a method is proposed for fabricating an optoelectronic component comprising at least one photodiode, the method comprising at least the steps of:
producing (1702) multiple epitaxial growths from a, at least on its upper part, p-doped semiconductor substrate to obtain a stack of semiconductor layers, the stack being composed, above the substrate (102), of an absorption layer (104) in a p-doped material, then of a lightly doped electron collection layer (106) having a large forbidden band and of a surface barrier layer (108-1, 108-2) having a large forbidden band; and
producing (1704) an n-doping-based pixelation at the surface barrier layer, the pixelation comprising metallizations (1706) to create electrical contacts (112, 118) for said at least one photodiode, firstly on the n-doped pixelated surface barrier layer and secondly on the p-doped upper part of the semiconductor substrate.

The invention provides a number of embodiments.

According to one particular aspect of the invention, the step of producing an absorption layer comprises a step of p-doping the material of said absorption layer in a uniform or graded manner.

According to one particular aspect of the invention, the step of producing an electron collection layer (106) comprises producing a collector region if said at least one photodiode is a UTC photodiode.

According to one particular aspect of the invention, the step of producing an electron collection layer (106) comprises producing an avalanche region if said at least one photodiode is an APD photodiode.

According to one particular aspect of the invention, the step of producing a surface barrier layer having a large forbidden band comprises epitaxially growing a barrier layer (108-1) based on a heavily n+-doped semiconductor material.

According to one particular aspect of the invention, the step of producing a surface barrier layer having a large forbidden band comprises a step of epitaxially growing a barrier layer (108-2) based on a not intentionally doped semiconductor material, and a step of n+-doping (110) the not intentionally doped barrier layer in a localized manner.

According to one particular aspect of the invention, the localized n+ doping step is performed by way of implantation or diffusion.

In one embodiment, the semiconductors used by the method of the invention are type-III-V semiconductors.

In one embodiment, the III-V-type semiconductors used by the method of the invention are InGaAs semiconductors on an InP substrate.

In one embodiment, the III-V-type semiconductors used by the method of the invention are InGaAsSb semiconductors on a GaSb substrate or superlattice semiconductors of the InGaAs/GaAsSb family on an InP substrate.

The subject of the invention is also a photodiode obtained using the method of the invention in all its variant embodiments.

The subject of the invention is also an optoelectronic component comprising at least one photodiode, this component being obtained using the method of the invention in all its variant embodiments.

### BRIEF DESCRIPTION OF THE DRAWINGS

Other features and advantages of the present invention will become more clearly apparent on reading the description that follows with reference to the following drawings:

FIGS. 1a and 1b respectively illustrate a known structure of a planar PIN diode made of InGaAs semiconductor material on an InP substrate, and a band diagram of such a PIN diode;

FIG. 2 illustrates a known band structure of a UTC photodiode;

FIG. 3 illustrates an example of a known mesa configuration for a UTC photodiode;

FIG. 4 illustrates a known band structure of an avalanche photodiode (APD) with an absorbent region made of undepleted or graded-doping InGaAs material;

FIG. 5 illustrates a pixelation process by way of localized diffusion of a p-type dopant;

FIG. 6 illustrates a mesa pixelation process with p+ doping during growth;

FIG. 7 illustrates a pixelation approach based on existing technologies where UTC or APD photodiode arrays would be produced to limit the dark current;

FIG. 8 illustrates a stack of semiconductor layers in one embodiment of the method for fabricating an optoelectronic component of the invention, where, contrary to the known state of the art, the buffer layer on the substrate on which the heterostructure is deposited is not of the N type;

FIGS. 9a-10a and 9b-10b illustrate, for each variant embodiment of the method of the invention, a heavily doped surface barrier layer having a large forbidden band;

FIGS. 11a and 11b illustrate, for each variant embodiment of the method of the invention, a metallization operation for N-type contacting;

FIGS. 12a and 12b illustrate, for each variant embodiment of the method of the invention, an etching operation to separate pixels;

FIG. 13a and FIG. 13b illustrate, for each variant embodiment of the method of the invention, an etching operation for P-type contacting;

FIG. 14a and FIG. 14b illustrate, for each variant embodiment, a passivation and interconnection operation for the common P contact;

FIG. 15A and FIG. 15b illustrate a variant embodiment of a passivation and interconnection operation;

FIG. 16A and FIG. 16b illustrate another variant embodiment of a passivation and interconnection operation;

FIG. 17 illustrates the main steps of the method of the invention.

### DETAILED DESCRIPTION

The references in the various figures are kept identical when they designate identical or similar elements.

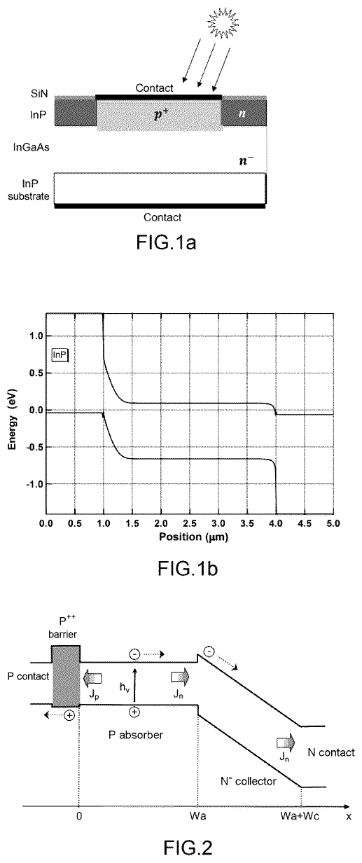

A few reminders are first provided about the diodes and in particular the photodiodes in support of FIGS. 1 to 4.

A photodiode is an optoelectronic component having the ability to detect radiation from the optical domain and transform it into an electrical signal. A photodiode is a semiconductor diode in which incident light radiation causes a variation in intensity. Photodiodes are typically used as photodiode arrays for earth observation applications and applications for locating and tracking a transmitting satellite or a ground station.

A known diode structure is presented in FIG. 1a, which shows a typical stack of a planar PIN diode made of InGaAs semiconductor material on an InP substrate, consisting of an undoped central region, referred to as intrinsic, I interposed between two P- and N-doped regions. In addition to the P+- and N+-doped layers typical of a diode, the PIN diode has a central region I whose doping is much lower. This region then acts as an intrinsic, that is to say undoped, semiconductor.

FIG. 1b illustrates a band diagram of an example of a PIN diode on InP substrate for InGaAs/InP bands. The internal electric field corresponds to the derivative of the conduction and valence bands. Here, the active InGaAs region with a thickness of 3 μm is located between the p-type InP window (abscissa x=1 μm) and the n-type InP contact (from x=4 μm). The active region has a depleted region, from x=1 μm to x=1.5 μm, which is a function of the doping, and a neutral region from x=1.5 μm to x=4 μm.

PIN diode structures are known to have a large electric field in the depleted InGaAs material, and to be very quickly degraded under irradiation.

Regarding the case of heterojunctions (a heterojunction is a junction between two semiconductors whose forbidden bands (gaps) are different, because the two semiconductors are different or because the junction forms between a metal and a semiconductor), it appears that, if small gaps are used for infrared, the only approaches to limit the generation of induced dark currents are to reduce the polarization of the diodes to limit the electric field in the junction, and to lower the temperature.

Reminder about photodiode families:

There are two major families of fast photodiodes, UTC (Uni-Traveling Carrier) photodiodes and APD (Avalanche PhotoDiode) photodiodes.

The UTC photodiode is broadly developed for its linearity vis-à-vis flux and its speed. This is permitted because electron transport is determined only by electrons. Indeed, the minority carrier electrons in the p-type absorbent region diffuse towards a collector region made of intrinsically undoped InP material, where they are accelerated and collected on the N-type contact side. The less mobile holes are themselves instantly collected on the P-type contact side. They do not scale the electrical transport, allowing the resistance of structures to high optical fluxes to be optimized while maintaining good frequency performance (by controlling other parameters such as electrical capacitance). The other advantage of this structure is limiting the dark current in the InGaAs layer in the absence of an electric field.

FIG. 2 illustrates a band structure of a UTC photodiode, with, from left to right:
a P contact typically made of heavily p-doped InGaAs material;
a barrier to block P⁺⁺ electrons, which is heavily p-doped;
an active region made of p-type InGaAs material. This assumes doping during growth and not by way of diffusion. Such doping may also be graded to optimize electron transport and balance the transit times of the two types of carriers. If the dark current remains slightly degraded in the present embodiment, an optimization of the MTF (Modulation Transfer Function) is expected in an array version;
multiple adaptation layers to ensure the continuity of the conduction band to the N− collector; and
a collector region where prevails the strongest electric field allowing the electrons to be routed to the N+ contact.

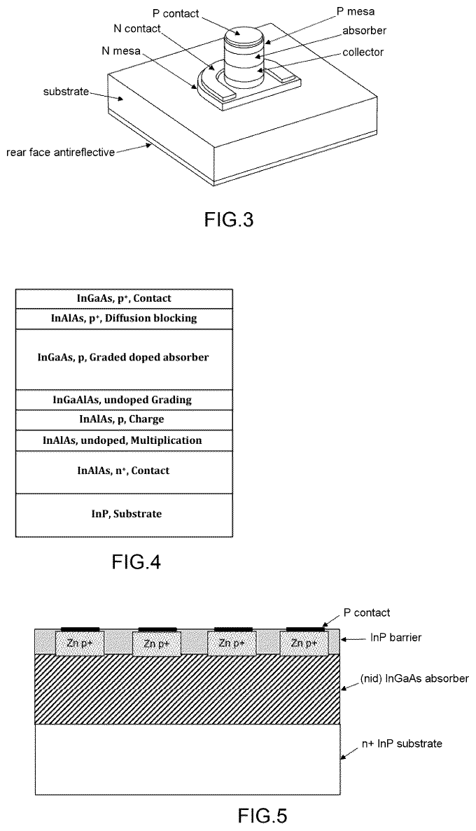

UTC diodes are available in a single-element format and in a mesa configuration. A mesa configuration obtained by etching the active region, such as for example illustrated in FIG. 3 for a photodiode illuminated by the rear face, is not optimal because the dark current is generated at the surface. This makes the passivation of the sides of the diode critical and limits the range balance in the case of a low-intensity light source.

An alternative for detecting weak signals in the case of a low-intensity light source may be to use an avalanche photodiode (APD) with an absorbent region made of undepleted InGaAs material or with graded doping as described for example in the article by N Li et al. “InGaAs/InAlAs Avalanche photodiode with undepleted absorber”, Applied Physicq Letters, vol. 82, No. 13, pp. 2175-2177, March 2003, and illustrated in FIG. 4. The electrons return to an avalanche region made of InAlAs, where they are multiplied. The electron transport of the holes is similar to that of the UTC diode in the absorber region. The p-doped charge region allows fine control of the electric field in the avalanche region. The advantage that the absorber is no longer depleted compared with a conventional APD diode is that the dark current is lower.

Thus, according to present knowledge, UTC and APD photodiodes with undepleted absorber or graded doping are a priori less sensitive to irradiation. They exist in a mesa format but they are then dependent on an effective passivation to guarantee a good range balance on optical links.

They could exist in diffused technology, but it would then be necessary to guarantee electrical insulation between photodiodes at the collector layer for UTCs, or at the avalanche region for APDs.

FIG. 5 illustrates a pixelation process by way of localized diffusion of a p-type dopant: for example zinc Zn in the case of an n-type or nid-type (i.e. not intentionally doped) InGaAs active region. This fabrication process is standard for InGaAs imagers and makes it possible to avoid producing mesas that are difficult to passivate and the source of significant dark currents. Typically, existing technologies use an N-type buffer layer on the substrate on which the PIN heterostructure is deposited.

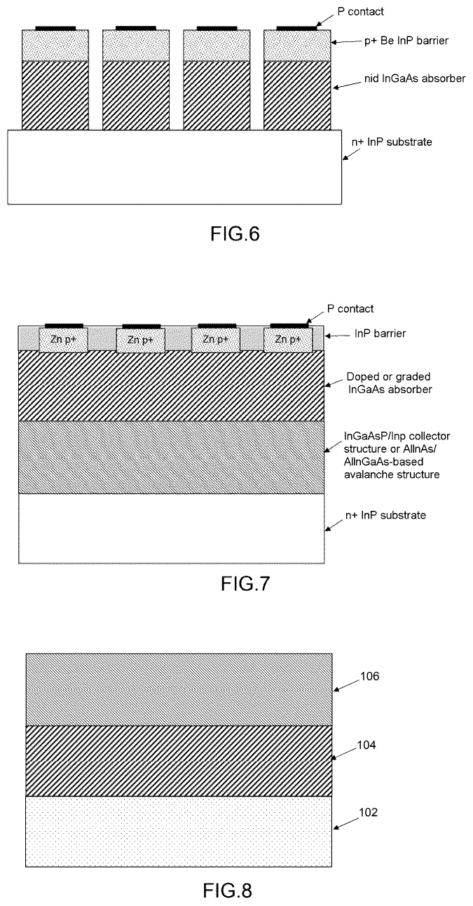

FIG. 6 illustrates a mesa pixelation process with p+ doping during growth (Be). The mesas expose the active region, in particular in the depleted region. This is where the generation of dark currents can become dramatic.

FIG. 7 illustrates a pixelation approach based on existing technologies where UTC or APD photodiode arrays would be produced with the aim of limiting the dark current. This would entail a Zn diffusion in the case of a p-type InGaAs active region. This active region is placed above the large gap in which most of the electric field is deployed, whether a UTC structure or an APD structure is involved.

As indicated, to overcome the disadvantages of known technologies for fabricating optoelectronic components, and to meet the need for specific applications, such as tracking between satellites, for example, the fabrication method of the invention can be used to obtain UTC or APD heterojunction photodiode structures with undepleted absorber or graded doping.

The advantage of these structures is that the electron collection electric field is outside the undepleted or graded-doping absorption region, which means that it is possible to benefit from greater robustness with respect to irradiation.

By moving the electron collection electric field to a layer with a wider forbidden band and/or that is easier to passivate, the dark currents will be smaller, in particular those generated in the absorber region.

Another advantage resulting from the structures obtained where the collector or avalanche layers and the N contact appear at the surface (allowing direct collection of the minority carrier electrons via an ROIC read circuit in an array version) is that they make it possible to benefit from components with large bandwidths (more than 10 to 20 GHz) for specific applications, such as inter-satellite tracking applications for merging tracking and fast detection functions.

FIG. 8 illustrates initial epitaxial growth operations to produce a stack of semiconductor layers (102, 104, 106, 108) from which an optoelectronic component according to the invention is produced.

As shown in FIG. 8, an absorption layer 104 intended to form the light absorption region of the photodiodes is produced from InGaAs material on a semiconductor substrate 102 made of InP material.

In a preferred embodiment as described, the semiconductors used by the method of the invention are InGaAs semiconductors on an InP substrate.

Variants can be adapted for other type-III-V materials where the material having the narrowest forbidden band is the most sensitive (superlattices of the InGaAs/GaAsSb family or quaternary InGaAsSb superlattices).

In a variant embodiment, the substrate 102 used as a support for the epitaxial growth of the absorber layer 104 may have a p+-doped upper part. The thickness of the p+-doped upper part is in the range from 100 nm to several microns, and the doping is greater than 10¹⁷ cm⁻³. This layer can be used to establish an epitaxy buffer if an n-type or semi-insulating substrate is kept. Indeed, this solution, but with a p-type InP substrate (as in the prior art), would have a lower quality and no transparency.

The semiconductor material of the absorber layer 104 is p-doped and, according to various embodiments, the doping is produced uniformly or is graded. The doping is produced by appropriate known means such as the introduction of a carbon (C) or beryllium (Be) dopant.

A lightly doped layer having a large forbidden band 106 is produced on the absorption layer 104, allowing the electrons to be collected. This layer 106 will be subjected to the strongest electric field present during the operation of the component which will be fabricated. The thickness of the lightly doped layer having a large forbidden band is in a range from a few tens of nanometres (nm) to a few hundred nm, depending on the properties targeted (avalanche voltage, electrical capacitance, etc.).

In one embodiment, the step of producing the lightly doped layer having a large forbidden band involves creating a collector region, if the photodiode of the optoelectronic component to be produced is a UTC photodiode. In one embodiment, the collector region is based on InGaAsP/InP material.

In one embodiment, the step of producing the lightly doped layer having a large forbidden band involves creating an avalanche region if the photodiode of the optoelectronic component to be produced is an APD photodiode. In one embodiment, the avalanche region is based on AlInAs/AlInGaAs material.

In other variant embodiments, the avalanche regions of the APD photodiodes can be in one of the following materials: INP, AlInAs, AlGaAsSb or AlInAsSb.

In other variant embodiments, the collectors of the UTC photodiodes can be produced from one of the following materials: InP or AlInAs.

In addition, a very wide variety of adaptation layers can be used.

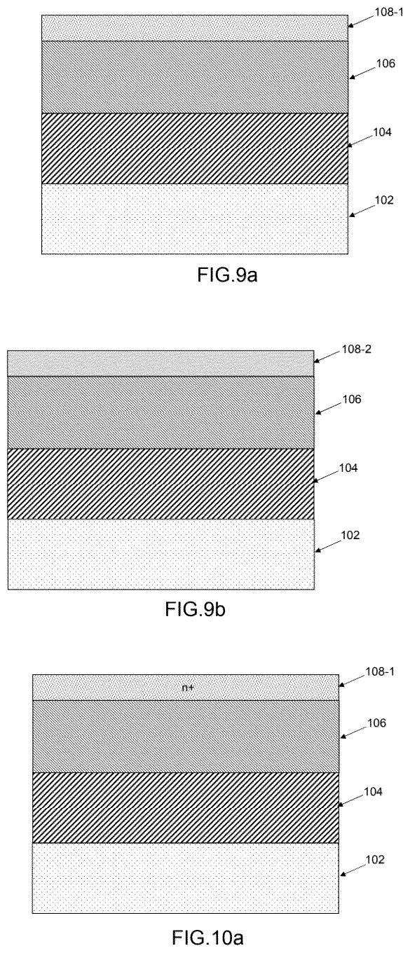

Advantageously, the optoelectronic component obtained by way of the method of the invention can be produced according to two technological versions: a so-called ‘semi-mesa’ version illustrated by FIGS. 9a to 16a and a so-called ‘diffused-junction’ version illustrated by FIGS. 9b to 16b.

FIGS. 9a and 9b illustrate, for each technological version of the method of the invention, the production, above the lightly doped layer having a large forbidden band 106, of a surface barrier layer having a large forbidden band.

According to the semi-mesa version of FIG. 9a, the surface barrier layer having a large forbidden band 108-1 is obtained by epitaxially growing a barrier layer made of InP, InAlAs, AlAsSb, AlGaAsSb or AlInAsSb material. In a preferred embodiment, the material is of the same type as for the collector.

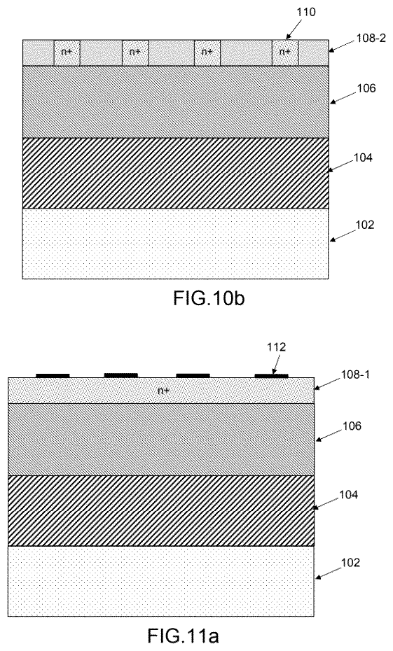

The surface barrier layer 108-1 having a large forbidden band is heavily n+-doped (illustrated in FIG. 10a) by way of a doping >10¹⁸ cm⁻³.

Preferably, a contact layer is produced to facilitate the ohmic contact.

According to the diffused-junction version of FIG. 9b, the surface barrier layer having a large forbidden band 108-2 is obtained by epitaxially growing a barrier layer having a thickness ranging from a few 100 nm to 1 μm, made of n or residual n (i.e. nid, not intentionally doped) semiconductor material. In one embodiment, the nid material is InP or InAlAs.

The epitaxial growth operation is followed according to FIG. 10b by a localized n+ doping operation, by way of a doping >10¹⁸ cm⁻³, allowing islands having heavily n+-doped local surfaces 110 to be obtained.

According to various embodiments, the localized n+ doping can be produced by way of implantation and possibly by way of diffusion of germanium (Ge) during the formation of an alloyed contact if the barrier layer 108-2 is sufficiently thin.

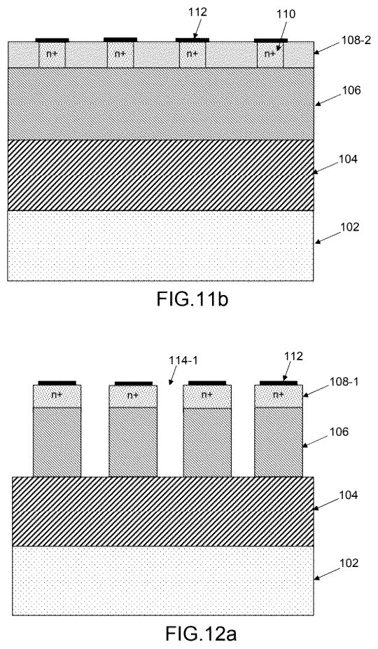

The complete pixelization operation, also referred to as the crosslinking operation, corresponds to multiple operations that are illustrated by FIGS. 11 to 16. Indeed, it is all of the operations either of FIGS. 11a to 16a or of FIGS. 11b to 16b that lead to the spatial separation of the photo-currents and to their collection (pixelation).

FIGS. 11a and 11b illustrate, for each technological version of the method of the invention, an operation of metallizing 112 the heavily n+-doped surfaces previously obtained, for N-type contacting(s).

In the variant of FIG. 11a, ohmic contacts are obtained on the barrier layer 108-1 by way of known metallization operations allowing the production of a contact or of a plurality of contacts of predefined geometry. The spacings between pads are minimized while remaining compatible with the design rules imposed by the fabrication methods.

In the variant of FIG. 11b, ohmic contacts are obtained on each heavily n+-doped local surface of the pads (110) obtained.

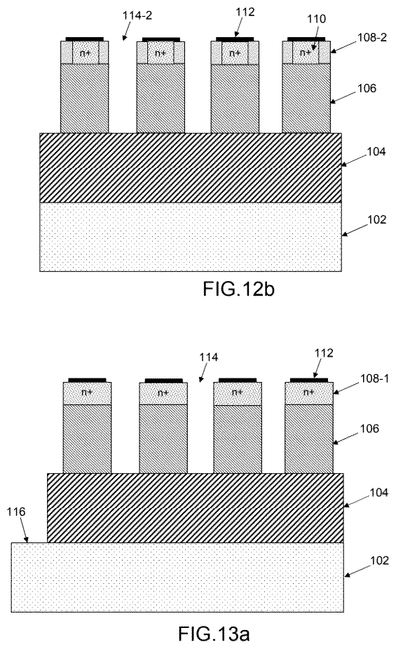

FIGS. 12a and 12b illustrate, for each implementation version of the method of the invention, an etching 114 and mesa passivation operation to obtain separate pixels.

In the variant of FIG. 12a, the etching 114-1 is produced by way of appropriate known means, such as an ICP (Induced Coupled Plasma) plasma etching in order to pass through the heavily doped barrier layer 108-1 and the lightly doped layer 106. The etching is stopped at the absorption layer 104. A mesa passivation is then produced.

In the variant of FIG. 12b, the etching 114-2 is produced by way of appropriate known means, such as an ICP plasma etching in order to pass through the nid surface barrier layer 108-2 and the lightly doped layer 106. The etching is stopped at the absorption layer 104. A mesa passivation is then produced.

In an alternative to the second implementation version, it may not be necessary to produce a mesa passivation after the etching, if it is determined that the crosstalk performance of the UTC or APD structures is satisfactory.

At the end of the etching and, where appropriate, mesa passivation operation, the method has made it possible to produce trenches that surround mesa structures, that is to say stacks of layers forming ohmic N-contact islands, resting on the absorption layer 104, which is itself resting on the substrate 102. This is the n-type common contact.

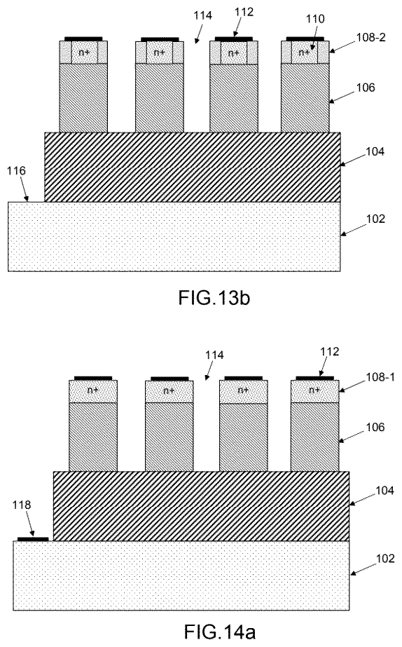

FIGS. 13a and 13b illustrate, for each implementation version of the method of the invention, an etching operation for common P-type contacting on the substrate 102. The etching 116 is produced by way of suitable known means (for example ICP) in order to pass through the absorption layer 104 in a region where it is visible at the surface, and in order to be stopped at the surface of the substrate 102.

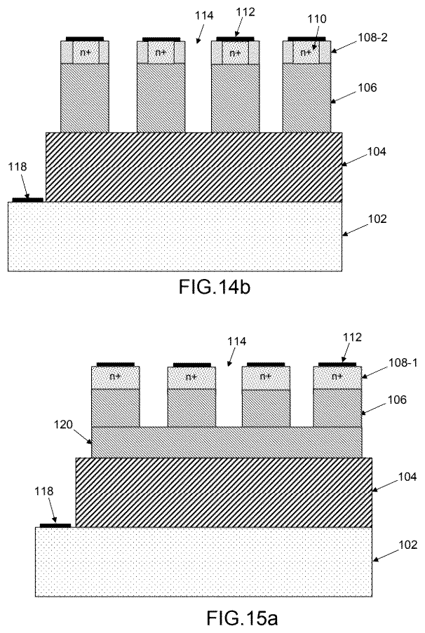

FIGS. 14a and 14b illustrate, for each implementation version, a passivation and electrical interconnection operation for the common P contact. The passivation is a deposit 118 made of SiN or SiOx material covering the edges of the mesas.

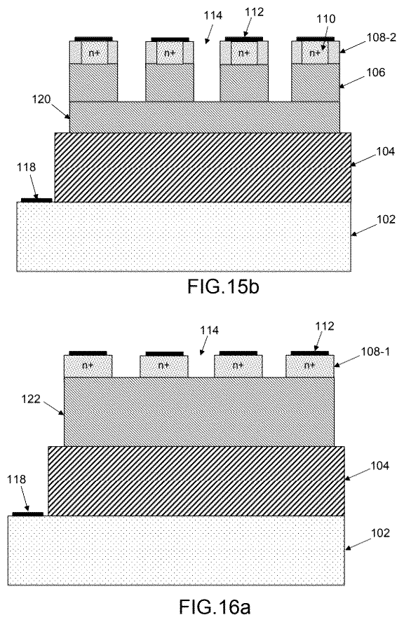

FIGS. 15a and 15b illustrate a variant embodiment of an electrical passivation and interconnection operation (120) that allows the absorber not to be exposed and limits the generation of dark current.

A layer having a larger gap than the absorber region must then have characteristics for the pair of parameters (doping, thickness) that make it possible to screen the surface charges.

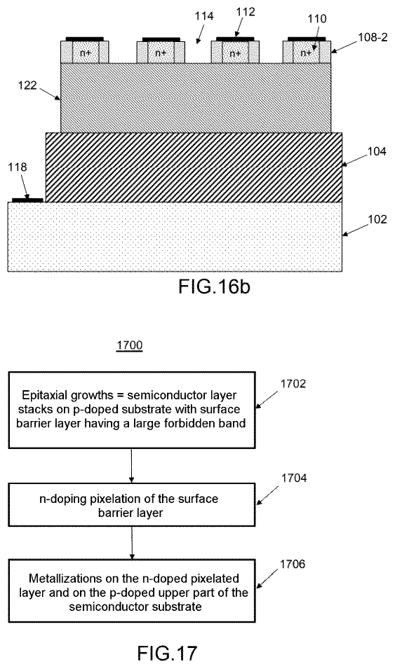

FIGS. 16a and 16b illustrate another variant embodiment of a passivation and electrical interconnection operation (120) where only the n+ contact is depleted. This solution is viable if the continuity of the collection layer (UTC) or avalanche layer (APD) does not generate crosstalk.

Two embodiments of the method of the invention have thus been described that allow the development of UTC or APD photodiode arrays with undepleted absorber or graded doping, so as to benefit from greater robustness with respect to irradiation, and to limit dark currents in the absorber region.

FIG. 17 illustrates the main steps of the method 1700 of the invention, detailed according to the different variants in FIGS. 8 to 16.

Thus, in a first step 1702, multiple epitaxial growths are produced from a, at least on its upper part, p-doped semiconductor substrate to obtain a stack of semiconductor layers, the stack being composed, above the substrate (102), of an absorption layer (104) in a p-doped material, then of a lightly doped electron collection layer (106) having a large forbidden band and of a surface barrier layer (108-1, 108-2) having a large forbidden band.

In a second step 1704, an n-doping pixelation of the surface barrier layer having a large forbidden band is produced, the pixelation comprising metallizations (1706) to create electrical contacts (112, 118) for the photodiode(s), firstly on the n-doped pixelated surface barrier layer and secondly on the p-doped upper part of the semiconductor substrate.

Advantageously, in the diffused-junction technological version, the passivation is optimized because no etching operation is performed. However, the risk is that the undepleted InGaAs material may degrade the MTF and crosstalk performance in an array version. Those skilled in the art will then be able to slightly gradate the absorber so as to make the collection of electrons more anisotropic. However, care must be taken to limit the value of the electric field in order to limit the increase in the dark current.

In the semi-mesa version, the epitaxially n+-doped barrier layer is etched at least. Depending on the etching and passivation performance of the UTC or APD structures, the etching can be carried out up to the absorber or otherwise, the advantage being to relax the constraint on the gradation of the doping of the InGaAs, or even to do away with it.

1. A method for fabricating an optoelectronic component comprising at least one photodiode, the method comprising at least the steps of:
producing multiple epitaxial growths from a, at least on its upper part, p-doped semiconductor substrate to obtain a stack of semiconductor layers, the stack being composed, above the substrate, of an absorption layer in a p-doped material, then of a lightly doped electron collection layer having a large forbidden band and of a surface barrier layer having a large forbidden band; and
producing an n-doping-based pixelation at the surface barrier layer, the pixelation comprising metallizations to create electrical contacts for said at least one photodiode, firstly on the n-doped pixelated surface barrier layer and secondly on the p-doped upper part of the semiconductor substrate.

2. The method according to claim 1, wherein the step of producing an absorption layer comprises a step of p-doping the material of said absorption layer in a uniform or graded manner.

3. The method according to claim 1, wherein the step of producing an electron collection layer comprises producing a collector region if said at least one photodiode is a UTC photodiode.

4. The method according to claim 1, wherein the step of producing an electron collection layer comprises producing an avalanche region if said at least one photodiode is an APD photodiode.

5. The method according to claim 1, wherein the step of producing a surface barrier layer having a large forbidden band comprises epitaxially growing a barrier layer based on a heavily n+-doped semiconductor material.

6. The method according to claim 1, wherein the step of producing a surface barrier layer having a large forbidden band comprises a step of epitaxially growing a barrier layer based on a not intentionally doped semiconductor material, and a step of n+-doping the not intentionally doped barrier layer in a localized manner.

7. The method according to claim 6, wherein the localized n+ doping step is performed by way of implantation or diffusion.

8. The method according to claim 1, wherein the semiconductors used by the method of the invention are type-III-V semiconductors.

9. The method according to claim 8, wherein the type-III-V semiconductors used by the method of the invention are InGaAs semiconductors on an InP substrate.

10. The method according to claim 9, wherein the type-III-V semiconductors used by the method of the invention are InGaAsSb semiconductors on a GaSb substrate or superlattice semiconductors of the InGaAs/GaAsSb family on an InP substrate.

11. A photodiode obtained by way of a fabrication method comprising at least the steps of claim 1.

12. An optoelectronic component comprising at least one photodiode according to claim 11.
